(19) United States
(12) Patent Application Publication
(10) Pub. No.: US 2016/0124806 A1
(43) Pub. Date: May 5, 2016

(54) Data Storage Device and Flash Memory Control Method

(71) Applicant: Silicon Motion, Inc., Jhubei City (TW)

(72) Inventor: Wei-Lun Yen, Tainan City (TW)

(73) Assignee: Silicon Motion, Inc.

(21) Appl. No.: 14/920,386

(22) Filed: Oct. 22, 2015

(30) Foreign Application Priority Data
Nov. 3, 2014 (TW) 103138007

(51) Int. Cl. G06F 11/10; G11C 29/52

(52) U.S. Cl. CPC G06F 11/1068; G11C 29/52

(57) ABSTRACT

A flash memory control method with high reliability. A control unit coupled between a host and a flash memory gathers statistics about commands performed on the flash memory. Based on the statistical result, the control unit is triggered to perform a sample check and correction procedure on the flash memory. The data within an endangered block failing to pass the sample check and correction procedure may be entirely moved to a spare block in the flash memory.

### CROSS REFERENCE TO RELATED APPLICATIONS

This application claims priority of Taiwan Patent Application No. 103138007, filed on Nov. 3, 2014, the entirety of which is incorporated by reference herein.

### BACKGROUND OF THE INVENTION

1. Field of the Invention

The present invention relates to data storage devices with flash memory and flash memory control methods.

2. Description of the Related Art

Flash memory, a data storage medium, is common in today's data storage devices. A NAND flash is one common type of flash memory.

For example, flash memory is typically used in memory cards, USB flash devices, solid-state drives, and so on. In another application with multi-chip package technology, a NAND flash chip and a controller chip are combined in one package as an embedded multi-media card (e.g. eMMC).

The storage space of a flash memory generally provides a plurality of physical blocks, and each physical block includes a plurality of physical pages. To release storage space for reuse, an erase operation has to be performed on a block-by-block basis, to release space one block at a time. When updating data, the new data is written into a spare space rather than being overwritten onto old data, and the old data has to be invalidated. Thus, the storage space management of flash memory is more complex than other storage mediums. A controller designed especially for flash memory is therefore called for.

Furthermore, the storage density of flash memory is considerably increased with the developing semiconductor manufacturing process. Thus, the data retention is more sensitive to the external environment. For example, erroneous data transition may occur in high or low temperature conditions. The number of error bits may exceed an error correctable limit of error checking and correction and lead to data being lost forever.

### BRIEF SUMMARY OF THE INVENTION

In the disclosure, for a data storage device using a flash memory as a non-volatile storage medium, a sample check and correction procedure is spontaneously triggered to be performed on the flash memory which considerably improves the data reliability of the flash memory.

A data storage device in accordance with an exemplary embodiment of the disclosure comprises a flash memory and a control unit. The control unit is coupled between a host and the flash memory to operate the flash memory in accordance with requests from the host. The control unit gathers statistics about commands performed on the flash memory and, based on a statistical result of the commands, the control unit is triggered to perform a sample check and correction procedure on the flash memory. In an exemplary embodiment, for an endangered block that fails to pass the sample check and correction procedure, the control unit moves the entire data of the endangered block to a spare block of a plurality of physical blocks of the flash memory.

In accordance with another exemplary embodiment of the disclosure, a flash memory control method comprises the following steps: gathering statistics about commands performed on a flash memory when operating the flash memory; and, based on a statistical result of the commands, triggering a sample check and correction procedure to be performed on the flash memory. In an exemplary embodiment, for an endangered block that fails to pass the sample check and correction procedure, the entire data of the endangered block is moved to a spare block of a plurality of physical blocks of the flash memory.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 depicts a data storage device 100 in accordance with an exemplary embodiment of the disclosure; and

FIG. 2 is a flowchart depicting a control procedure of the flash memory 102 in accordance with an exemplary embodiment of the disclosure.

### DETAILED DESCRIPTION OF THE INVENTION

The following description shows exemplary embodiments for carrying out the invention. This description is made for the purpose of illustrating the general principles of the invention and should not be taken in a limiting sense. The scope of the invention is best determined by reference to the appended claims.

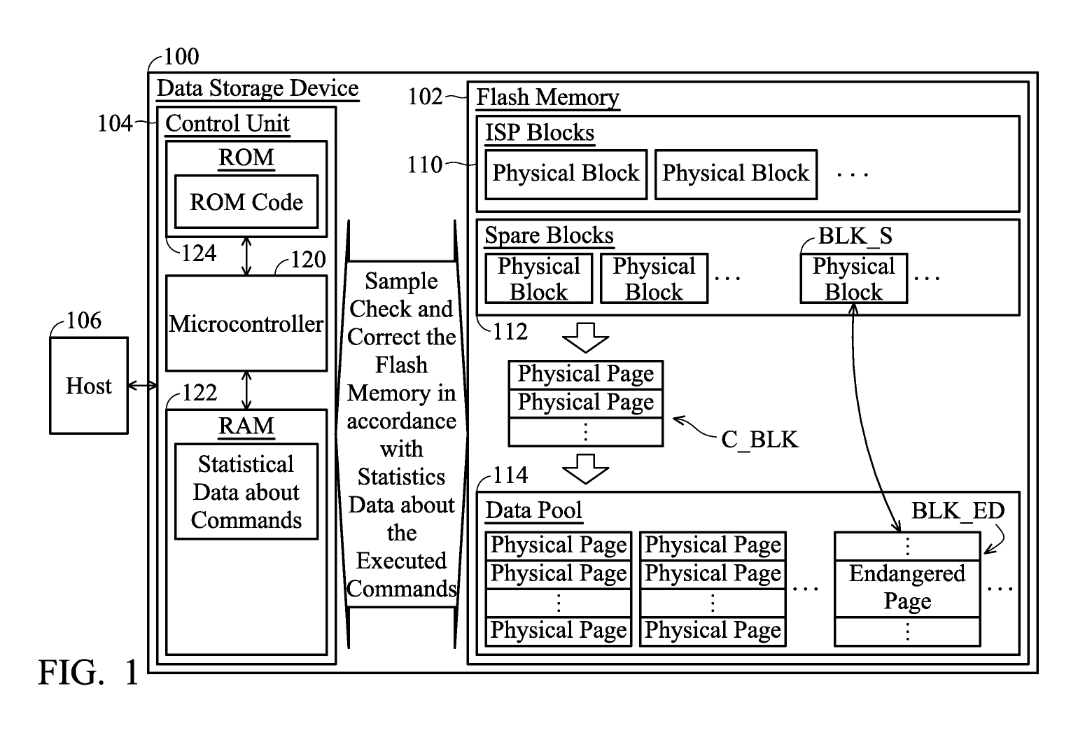

FIG. 1 depicts a data storage device 100 in accordance with an exemplary embodiment of the disclosure, which comprises a flash memory 102 and a control unit 104. The control unit 104 is coupled between a host 106 and the flash memory 102.

The storage space of the flash memory 102 is allocated to provide ISP (in-system-program) blocks 110, spare blocks 112, a run-time write block C_BLK and a data pool 114. The ISP blocks 110 store in-system programs (ISPs). The run-time write block C_BLK is allocated from the spare blocks 112 for reception of write data. When the collection of write data on the run-time write block C_BLK is finished, the run-time write block C_BLK is pushed into the data pool 114.

The control unit 104 includes a microcontroller 120, a random access memory 122 (e.g. an SRAM), and a read-only memory 124. The read-only memory 124 stores read-only codes (e.g. ROM code). The microcontroller 120 operates by executing the ROM code stored in the read-only memory 124 or/and by executing the ISPs stored in the ISP blocks 110 of the flash memory 102 and, accordingly, the control unit 104 operates the flash memory 102 in accordance with commands issued from the host 106 and gathers statistics about the commands performed on the flash memory 102. According to the statistical result of the commands, the control unit 104 is triggered to perform a sample check and correction procedure on the flash memory 102. In this manner, the control unit 104 spontaneously sample checks and corrects the flash memory 102 and effectively solves the problem of data loss with data which has not been refreshed for a long time. The data reliability of the flash memory 102, therefore, is improved. The gathered statistical data about the commands performed on the flash memory 102 may be temporarily stored in the random access memory 122. In addition to the commands issued from the host 106, the statistics gathering is also performed on the commands that operate the flash memory 102 according to the programs executed by the microcontroller 120.

In an exemplary embodiment, the physical block fails to pass the sample check and correction procedure is regarded as an endangered block. The control unit 104 is configured to move the entire data of the endangered block to a spare block of a plurality of physical blocks of the flash memory 102. In accordance with an exemplary embodiment, in the endangered block, there is at least one physical page error checked and corrected and resulting in a number of error bits not exceeding an error correctable limit but exceeding a threshold number.

For example, when the sample check and correction procedure shows that there is one endangered block BLK_ED in the data pool 114 (i.e., there is an endangered page in the endangered block BLK_ED that the endangered page processed by an error checking and correction process corresponds to an error bit number not exceeding an error correctable limit but exceeding a threshold number), the control unit 104 moves the entire data of the endangered block BLK_ED to a block BLK_S allocated from the spare blocks 112 of the flash memory 102. Such a complete data movement of the entire endangered block BLK_ED benefits wearing leveling between the physical blocks. In an exemplary embodiment, every time the sample check and correction procedure is performed, the control unit 104 selects one physical block of the plurality of physical blocks of the flash memory 102 to be partially checked and corrected. For example, one of the physical blocks having the lower erase counts in the flash memory 102 may be selected by the control unit 104 for the partially data checking and correction. In this manner, the control unit 104 spontaneously samples and examines the blocks that have not been refreshed for a long time. The data transition caused by environmental situations and make the storage data endangered may be timely corrected by the control unit 104.

The commands operated on the flash memory 102 and gathered by the control unit 104 in statistics may include read commands, write commands, erase commands, garbage collection commands and so on.

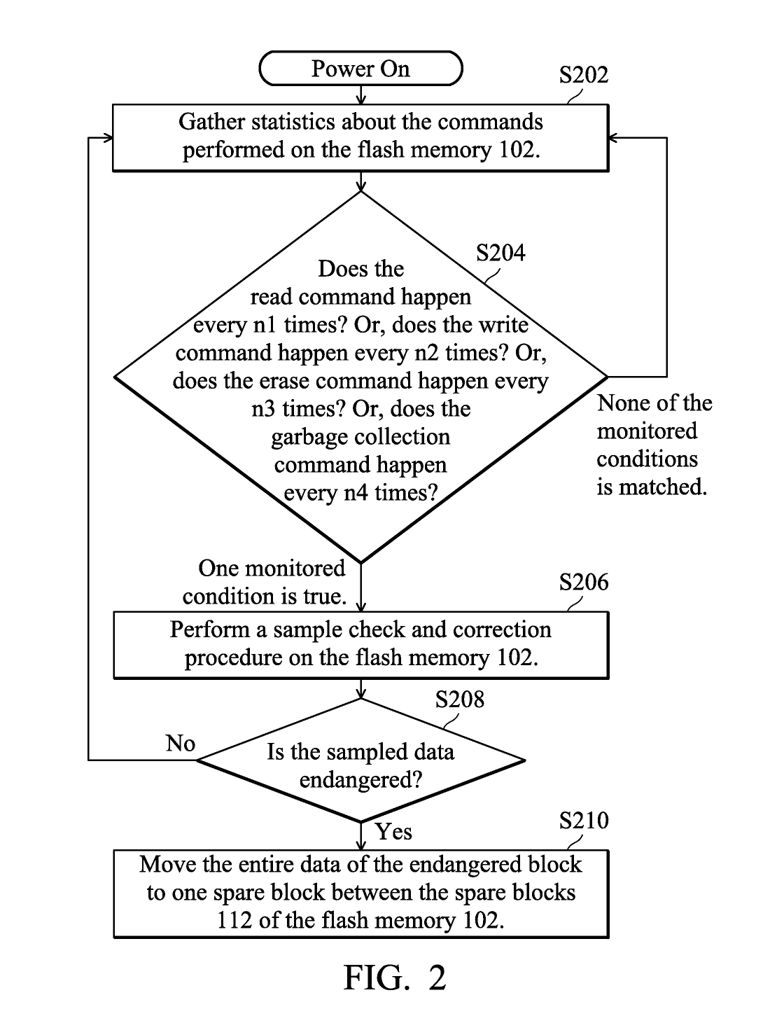

FIG. 2 is a flowchart depicting a control procedure of the flash memory 102 in accordance with an exemplary embodiment of the disclosure. When the data storage device 100 is powered on, the control unit 104 operates the flash memory 102 in accordance with the requests from the host 106. The commands gathered in statistics are not limited to the commands issued from the host 106. The commands operating the flash memory 102 in accordance with the programs executed by the microcontroller 120 may be gathered in statistics as well. In the exemplary embodiment depicted in FIG. 2, read commands or/and write commands or/and erase commands or/and garbage collection commands may be gathered in statistics. When it is determined in step S204 that the read command happens every n1 times, or the write command happens every n2 times, or the erase command happens every n3 times or the garbage collection command happens every n4 times, step S206 is performed to perform a sample check and correction procedure on the flash memory 102. In an exemplary embodiment, every time step S206 is performed, one physical block of the plurality of physical blocks of the flash memory 102 is selected and only a part of the selected physical block is checked and corrected (e.g., by a partial error checking and correction process on the selected physical block). In step S208, it is determined whether the sampled data is endangered (e.g. determining whether the sampled physical page processed by an error checking and correction process corresponds to an error bit number not exceeding an error correctable limit but exceeding a threshold number.) When the sampled data is endangered, step S210 is performed to move the entire data of the endangered block to one spare block between the spare blocks 112 of the flash memory 102. When it is determined in step S208 that none of the sampled data is endangered, the flow returns to step S202. Furthermore, when it is determined in step S204 that the monitored conditions all are not matched, the flow also returns to step S202.

In an exemplary embodiment, n4 is 1. The sample check and correction procedure is performed on the flash memory 102 every time a garbage collection command happens.

The invention further involves flash memory control methods, which are not limited to any specific controller architecture. Furthermore, any technique using the aforementioned concept to control a flash memory is within the scope of the invention.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A data storage device, comprising:
a flash memory; and
a control unit, coupled between a host and the flash memory to operate the flash memory in accordance with requests from the host,
wherein:
the control unit gathers statistics about commands performed on the flash memory and, based on a statistical result of the commands, the control unit is triggered to perform a sample check and correction procedure on the flash memory.

2. The data storage device as claimed in claim 1, wherein:
when an endangered block failing to pass the sample check and correction procedure, the control unit moves entire data of the endangered block to a spare block of a plurality of physical blocks of the flash memory.

3. The data storage device as claimed in claim 2, wherein:
in the endangered block, there is at least one physical page error checked and corrected and resulting in a number of error bits not exceeding an error correctable limit but exceeding a threshold number.

4. The data storage device as claimed in claim 2, wherein:
the control unit is triggered to perform the sample check and correction procedure on the flash memory when performing a read command every n1 times on the flash memory; and
n1 is a number.

5. The data storage device as claimed in claim 2, wherein:
the control unit is triggered to perform the sample check and correction procedure on the flash memory when performing a write command every n2 times on the flash memory; and
n2 is a number.

6. The data storage device as claimed in claim 2, wherein:
the control unit is triggered to perform the sample check and correction procedure on the flash memory when performing an erase command every n3 times on the flash memory; and
n3 is a number.

7. The data storage device as claimed in claim 2, wherein:
the control unit is triggered to perform the sample check and correction procedure on the flash memory when performing a garbage collection command every n4 times on the flash memory; and
n4 is a number.

8. The data storage device as claimed in claim 7, wherein n4 is 1.

9. The data storage device as claimed in claim 2, wherein:
every time the sample check and correction procedure is performed, the control unit selects one physical block of a plurality of physical blocks of the flash memory to be partially checked and corrected.

10. The data storage device as claimed in claim 9, wherein:
the control unit selects from the physical blocks having lower erase counts in the flash memory for the physical block to be partially checked and corrected by the sample check and correction procedure.

11. A flash memory control method, comprising:
gathering statistics about commands performed on a flash memory when operating the flash memory; and
based on a statistical result of the commands, triggering a sample check and correction procedure to be performed on the flash memory.

12. The flash memory control method as claimed in claim 11, further comprising:
when an endangered block fails to pass the sample check and correction procedure, moving entire data of the endangered block to a spare block of a plurality of physical blocks of the flash memory.

13. The flash memory control method as claimed in claim 12, wherein:
in the endangered block, there is at least one physical page error checked and corrected and resulting in a number of error bits not exceeding an error correctable limit but exceeding a threshold number.

14. The flash memory control method as claimed in claim 12, wherein:
the sample check and correction procedure is triggered to be performed on the flash memory when a read command is performed on the flash memory every n1 times; and
n1 is a number.

15. The flash memory control method as claimed in claim 12, wherein:
the sample check and correction procedure is triggered to be performed on the flash memory when a write command is performed on the flash memory every n2 times; and
n2 is a number.

16. The flash memory control method as claimed in claim 12, wherein:
the sample check and correction procedure is triggered to be performed on the flash memory when an erase command is performed on the flash memory every n3 times; and
n3 is a number.

17. The flash memory control method as claimed in claim 12, wherein:
the sample check and correction procedure is triggered to be performed on the flash memory when a garbage collection command is performed on the flash memory every n4 times; and
n4 is a number.

18. The flash memory control method as claimed in claim 17, wherein n4 is 1.

19. The flash memory control method as claimed in claim 12, wherein:
every time the sample check and correction procedure is performed, one physical block of a plurality of physical blocks of the flash memory is selected to be partially checked and corrected.

20. The flash memory control method as claimed in claim 19, wherein:
the physical block to be partially checked and corrected by the sample check and correction procedure is selected from the physical blocks having lower erase counts in the flash memory.
